(19) United States
(12) Patent Application Publication
(10) Pub. No.: US 2017/0217764 A1
(43) Pub. Date: Aug. 3, 2017

(54) CMOS-MEMS RESONANT TRANSDUCER AND METHOD FOR FABRICATING THE SAME

(71) Applicant: NATIONAL TSING HUA UNIVERSITY, HSINCHU (TW)

(72) Inventors: SHENG-SHIAN LI, Taoyuan City (TW); CHAO-YU CHEN, HSINCHU (TW); MING-HUANG LI, HSINCHU (TW)

(21) Appl. No.: 15/175,724

(22) Filed: Jun. 7, 2016

(30) Foreign Application Priority Data
Jan. 30, 2016 (TW) 105103057

(51) Int. Cl. B81B 7/02; B81C 1/00

(52) U.S. Cl. CPC B81B 7/02; B81C 1/00333

(57) ABSTRACT

A CMOS-MEMS resonant transducer and a method for fabricating the same are disclosed, which provide the CMOS-MEMS resonant transducer having narrow gaps(<500 nm) with high yield by etching a well-defined free-free beam structure, furthermore, the TiN layers disposed at the bottom of the resonant body may efficiently reduce the frequency drift due to electrostatic charges. The method for fabricating the CMOS-MEMS resonant transducer is also adapted to the processes of CMOS-MEMS platform with various scales, which provides routing and MEMS design flexibility.

### CROSS-REFERENCE TO RELATED APPLICATION

This application claims the benefit of Taiwan Patent Application No. 105103057, filed on Jan. 30, 2016, in the Taiwan Intellectual Property Office, the disclosure of which is incorporated herein in its entirety by reference.

### BACKGROUND OF THE INVENTION

1. Field of the Invention

The present invention relates to a CMOS-MEMS resonant transducer and a method for fabricating the same, more specifically, the present invention relates to a CMOS-MEMS resonant transducer and a method for fabricating the same based on existing CMOS-MEMS platform, in that the resonant body is disposed with a TiN layer to improve electrostatic charge conductivity and frequency stability.

2. Description of the Related Art

The demand for Internet of Things and wearable devices is soaring in recent years, which propels the development of smart sensing systems. Benefiting from the mass production and circuit integration capability, commercially viable CMOS-MEMS platform provides a cost-effective scheme for sensing system integration, which includes functions of timing reference, signal processing and multi-sensors construction.

However, currently the weak electrostatic coupling capability is still a major obstacle for the practical implementation, especially for the capacitive resonant transducer. To tackle this problem, a minuscule air gap is need between movable elements and driving electrodes, in order to reduce the equivalent motional impedance of the resonator and improve the output signal.

Although techniques such as using double polysilicon configuration in the 0.35 μm CMOS-MEMS process to achieve 40 nm miniscule transducer gap is available, such technique wastes the limited transducer area and possesses low yield. On the other hand, despite advancement in oxide-rich resonant transducer with high Q factor having 180 nm gap, it is hard to further apply advanced fabrication process to such resonant transducer due to the limitation of monocrystalline-polycrystalline silicon process.

Therefore, a high precision fabrication process is needed, which has the ability to provide a CMOS-MEMS resonant transducer and a method for fabricating the same with narrow transducer gap, high yield rate and effective electrostatic charge conductivity.

### SUMMARY OF THE INVENTION

In order to solve the aforementioned problems, the aim of the present invention is to provide a method for fabricating the CMOS-MEMS resonant transducer, which is based on the CMOS-MEMS platform, the CMOS-MEMS platform at least sequentially includes passivation layer, a plurality of dielectric layers with a plurality of titanium nitride (TiN)-metal-TiN composite layers therein, and a plurality of metal-TiN composite layers, wherein the method includes: etching the passivation layer at both sides of the resonant body region in the middle of the CMOS-MEMS platform so as to define the resonant body region, an etching region adjacent to both sides of the resonant body region, and a wire bonding region adjacent to the etching region; etching the plurality of the TiN-metal-TiN composite layers and the plurality of metal-TiN composite layers in the etching region to expose the dielectric layer in the etching region; etching the passivation layer in the wire bonding region and the exposed dielectric layer in the etching region at both sides of the resonant body region to expose the metal-TiN composite layer in the wire bonding region, and causing TiN-metal-TiN composite layer at the bottom of the etching region and the resonant body region to expose the portion thereof belonging to the etching region; etching the TiN layer on the TiN-metal-TiN composite layer in the etching region; etching the metal layer of the wire bonding region, resonant body region and the etching region, making the resonant body coated with the dielectric layer suspended, and forming the TiN layers facing each other, wherein the TiN layers are at the bottom of the resonant body and the portion of the etched CMOS-MEMS platform opposite the resonant body; etching the TiN layer in the wire bonding region and the etching region to expose the dielectric layer in the wire bonding region and the etching region; and etching the dielectric layer in the wire bonding region and the etching region, exposing the TiN-metal-TiN composite layer in the wire bonding region to serve as probing pad for subsequent wire bonding process.

Preferably, in the step for defining the resonant body region, the etching region and the wire bonding region, the etching process may further be applied to simultaneously etch the passivation layer on the resonant body region, etching region and the wire bonding region; and to etch the dielectric layer in the etching region, in order to expose the metal-TiN composite layer in the wire bonding region and to cause the TiN-metal-TiN composite layer at the bottom of the etching region and the resonant body region to expose the portion thereof belonging to the etching region.

Preferably, the plurality of TiN-metal-TiN composite layers and the plurality of metal-TiN composite layers in the dielectric layer further may include a plurality of interconnected metal wirings therebetween.

Preferably, the resonant body may be connected to the etched CMOS-MEMS platform through at least one dielectric layer, making the resonant body attach to the etched CMOS-MEMS platform in a suspended manner.

Preferably, the area of the TiN layer at the bottom of the resonant body and the portion of the CMOS-MEMS platform opposite the resonant body is equivalent.

Preferably, the gap between the bottom of the resonant body and the portion of the CMOS-MEMS platform corresponding to the resonant body is lesser than 500 nm.

Preferably, in the step for defining the resonant body region, the etching region and the wire bonding region may further include defining a plurality of resonant body regions, the etching region interposing the plurality of resonant body regions and surrounding the plurality of resonant body regions, and the wire bonding region surrounding the plurality of resonant body regions and the etching region, so as to form a plurality of resonant bodies.

Preferably, the step for making the resonant body suspended may further include using semiconductor fabrication process to fabricate additional resonant body, and forming an electrode with a low temperature deposition process depositing nitrides or tungsten compound at the wire bonding region.

In accordance with another aim of the present invention, a CMOS-MEMS resonant transducer is provided. The CMOS-MEMS resonant transducer includes: the silicon substrate, the first dielectric layer, the second dielectric layer, the third dielectric layer, a pair of TiN layers and a plurality of TiN-metal-TiN composite layers. The silicon substrate is defined with the resonant body region, the etching region surrounding the resonant body region, and the wire bonding region surrounding the etching region. The first dielectric layer is disposed on the silicon substrate, covers the silicon substrate, and includes a polysilicon layer disposed in the resonant body region. The second dielectric layer is disposed in the wire bonding region. The third dielectric layer is disposed on the first dielectric layer in the resonant body region, while connected to the first dielectric layer via at least one resonant body support element, so as to form a resonant body coated with the dielectric layer and suspended in the resonant body region. The pair of TiN layers respectively cover a bottom of the resonant body and a portion of the third dielectric layer opposite the resonant body excluding the at least one resonant body support element. The plurality of TiN-metal-TiN composite layers are interconnected via metal wirings and disposed in the second dielectric layer and the resonant body. Wherein, the top portion of the second dielectric layer and the resonant body exposing the top portion of the plurality of TiN-metal-TiN composite layers; and the plurality of TiN-metal-TiN composite layers exposed in the wire bonding region subsequently serve as a probing pad.

Preferably, the area of the TiN layers at the bottom of the resonant body is equivalent to the area of the portion of the third dielectric layer opposite the resonant body.

Preferably, the gap between the bottom of the resonant body and the portion of the third dielectric layer opposite the resonant body may be lesser than 500 nm.

Preferably, the silicon substrate may further include a plurality of resonant body regions, the etching region interposing the plurality of resonant body regions and surrounding the plurality of resonant body regions, and the wire bonding region surrounding the plurality of resonant body regions and the etching region, so as to form a plurality of resonant bodies.

Preferably, the CMOS-MEMS resonant transducer may further include an additional resonant body fabricated using semiconductor fabrication process, and an electrode formed with low temperature deposition process depositing nitrides or tungsten compound at the wire bonding region.

To summarize, the CMOS-MEMS resonant transducer and the method for fabricating the same according to the present application can fabricate the resonant transducer with high yield and precision in addition to having free-free beam structure, support beam constructed by dielectric material, gap design with less than 500 nm, and the bottom of the resonant body structure formed from TiN layer coated silicon dioxide. Such invention can provide resonant transducer with low motional impedance as well as eliminate frequency drift due to the charge accumulation at the bottom of the resonant body. Besides, the CMOS-MEMS resonant transducer of the present invention has high adaptability to CMOS-MEMS process platform of various scales as well as matches the commercial platforms for the fabrication process of various manufacturers.

### BRIEF DESCRIPTION OF THE DRAWINGS

Hereinafter, various features and advantages of the present invention will be set forth in detail in the form of preferred embodiments along with reference to the accompanying drawings, wherein:

FIG. 1 is a plan view of the configuration of the CMOS-MEMS resonant transducer of the present invention.

FIG. 2 is a sectional view of the CMOS-MEMS resonant transducer in the FIG. 1 taken along line I-I.

FIGS. 3A and 3B are respectively the perspective view and the schematic diagram illustrating the operation of the resonant body in the CMOS-MEMS resonant transducer of the present invention.

FIGS. 4A and 4B are respectively the sectional views of the CMOS-MEMS resonant transducer in the FIG. 3A taken along line II-II.

FIGS. 5A to 5D are respectively the sectional views illustrating every step of the method for fabricating the CMOS-MEMS resonant transducer according to an embodiment of the present invention.

FIGS. 6A to 6C are respectively the plan view SEM (scanning electron microscope), side view SEM taken along line and the partially magnified sectional view SEM of the resonant transducer fabricated using the method for fabricating the CMOS-MEMS resonant transducer of the present invention.

FIGS. 7A to 7D are respectively the sectional view illustrating every step of the method for fabricating the CMOS-MEMS resonant transducer according to another embodiment of the present invention.

FIGS. 8A to 8F are respectively the experimental scheme and measurement results for the frequency characteristics of the CMOS-MEMS resonant transducer of the present invention.

FIG. 9 is a sectional diagram illustrating the CMOS-MEMS resonant transducer according to yet another embodiment of the present invention.

### DESCRIPTION OF THE PREFERRED EMBODIMENTS

Various aspects like the technical features, advantages or content of the present invention will be set forth in detail in the form of preferred embodiments hereinafter, description will be made along with reference to the attached drawings, which are solely illustrative and serve to provide better understanding of the present invention only, the scale and/or proportion of any portion of the drawing do not represent the actual configuration of the invention, hence the scale, proportion or shape in the drawings should not be misconstrued as limiting the scope of the invention.

Hereinafter, the term “and/or” refers to the inclusion of any or all combinations of one or more listed items associated therewith. The term ‘at least one’ prefixing an item listing applies to all items in the list instead of the individual item of the list.

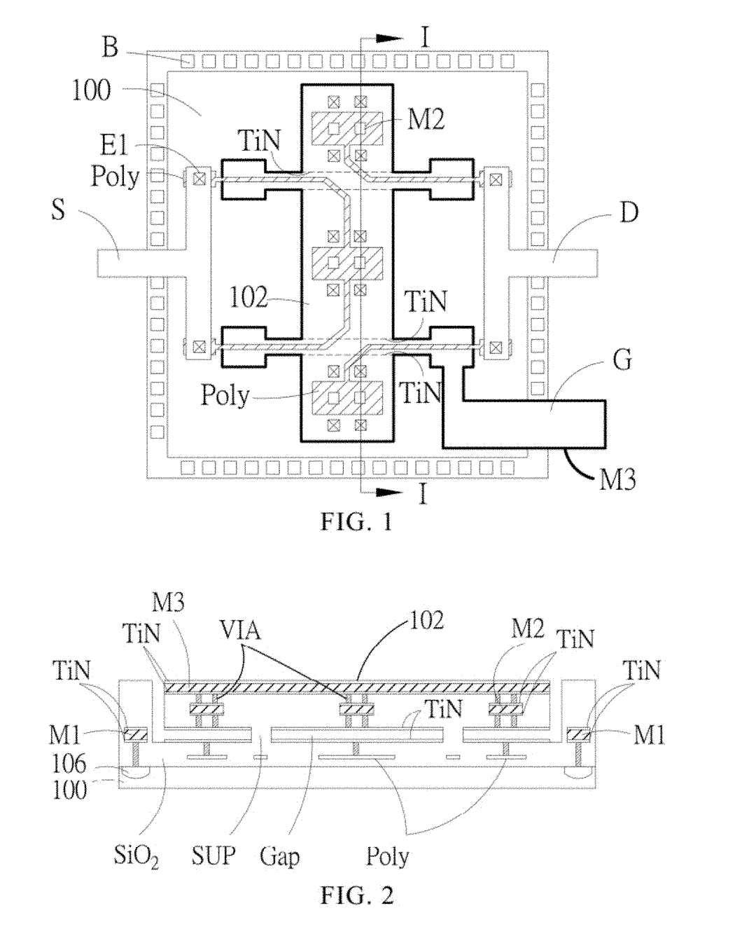

Refer to FIG. 1 and FIG. 2, which respectively illustrate the plan view of the configuration of the CMOS-MEMS resonant transducer and the sectional view of the CMOS-MEMS resonant transducer taken along line I-I. As shown in the drawings, the CMOS-MEMS resonant transducer 1 of the present invention is disposed on the P-type silicon substrate 100 using the free-free beam structure with four contact points configuration, whereas the upper portion of the silicon substrate 100 is covered with silicon dioxide layer to serve as insulation for transistor array, which is disposed below the free-free beam resonator array, and an excellent design can be obtained with layout technique by utilizing the CMOS-MEMS process platform. In other words, a resonant transistor can be obtained with the configuration, which mainly includes a resonator and a transistor, having a gate electrode G that can vibrate, and affect the current signal in the channel directly. Specifically, CMOS-MEMS resonant transducer includes a gate electrode G, a source electrode S, and a drain electrode D, and connects to the interior of a resonant body 102 made mainly from silicon dioxide via buried polysilicon electrode Poly and electrode E1. Besides, the resonant body 102 includes an electrode formed from a plurality of TiN-metal-TiN composite layers; for example, the surface is covered with a third electrode M3, which is further connected to a second electrode M2 via a metal wiring VIA. The resonant body 102 is suspended on the silicon substrate 100 with support beams SUP made from silicon dioxide (SiO₂), which generates air gap GAP to reduce the equivalent motional impedance of the resonator, increases output signal, as well as reduces the vibrational loss and serves as the fixing node on the resonant body 102 to improve the quality factors. In a preferred embodiment of the present invention, the air gap GAP is lesser than 500 nm, in order to match commercial platforms for fabrication process of different manufacturers, such as TSMC, UMC, and GlobalFoundries. In the best mode according to the present application, the air gap GAP can be precisely 400 nm. Furthermore, the perimeter of the silicon substrate 100 can be disposed with a plurality of ground terminals serving as base electrode B so as to reduce noise.

Apart from that, when the resonant body 102 is operating under direct current (DC), the oxides between the electrodes may cause frequency drifts due to the effect of electrostatic coupling. Alternating current can be adopted to eliminate the frequency drift, however, the architecture of the present transistor is not suitable to work under alternating current, and an additional power control unit is required to achieve this, which causes great inconvenience. As a solution, the bottom of the resonant body 102 of the present invention is covered with TiN layer TiN while the portion of the silicon dioxide layer under the resonant body 102 corresponding to the resonant body 102 is covered with the TiN layer TiN accordingly, and both of them have equivalent area in order to improve the electrostatic current conduction and eliminate the frequency drift. What is noteworthy is that the TiN layer TiN serves as the anti-reflation layer during the photolithography process in the CMOS-MEMS platform. Hence, there is no need for the additional sputtered coating of TiN layer TiN with the configuration of the present embodiment, which improves the flexibility of the fabrication process.

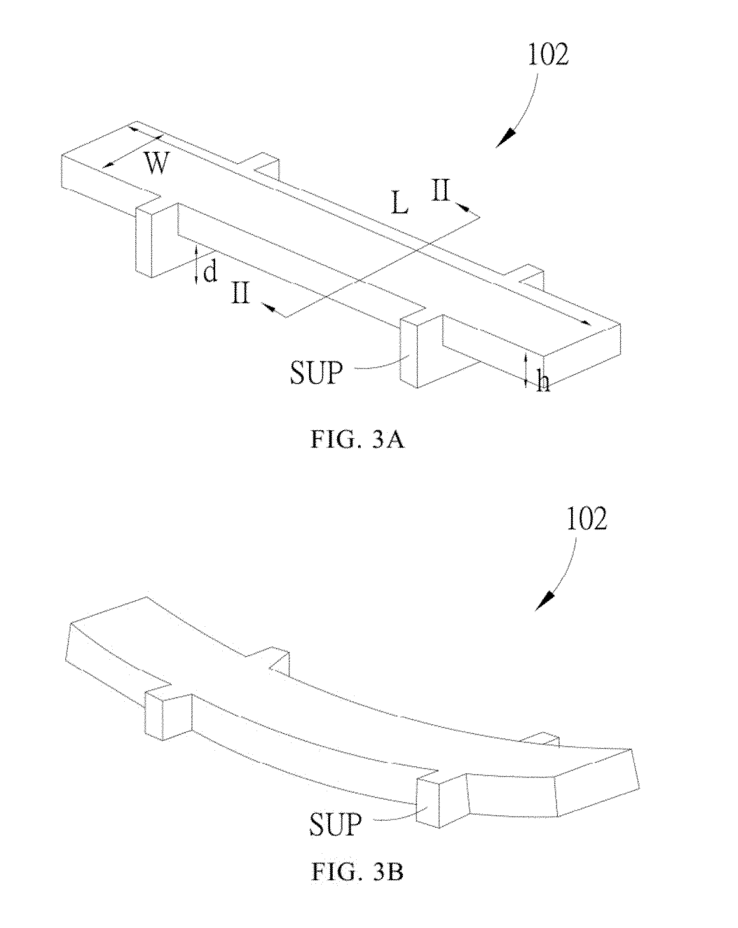

Refer to the FIGS. 3A to 3B, which are respectively the perspective view and the schematic diagram illustrating the operation of the resonant body of the CMOS-MEMS resonant transducer of the present invention. As can be appreciated in FIG. 3A, the resonant body 102 is a structure of free-free beam having length L=60 μm, width W=9 μm, height h=3.4 μm, as well as gap distance d=400 nm. When a voltage is applied to the gate electrode G, the resonant body 102 will bend as shown in FIG. 3B due to the electrostatic effect at the bottom of the resonant body 102, and the support beam SUP placed at the node of the free-free beam can reduce the resonant energy loss, thus improving the quality factor.

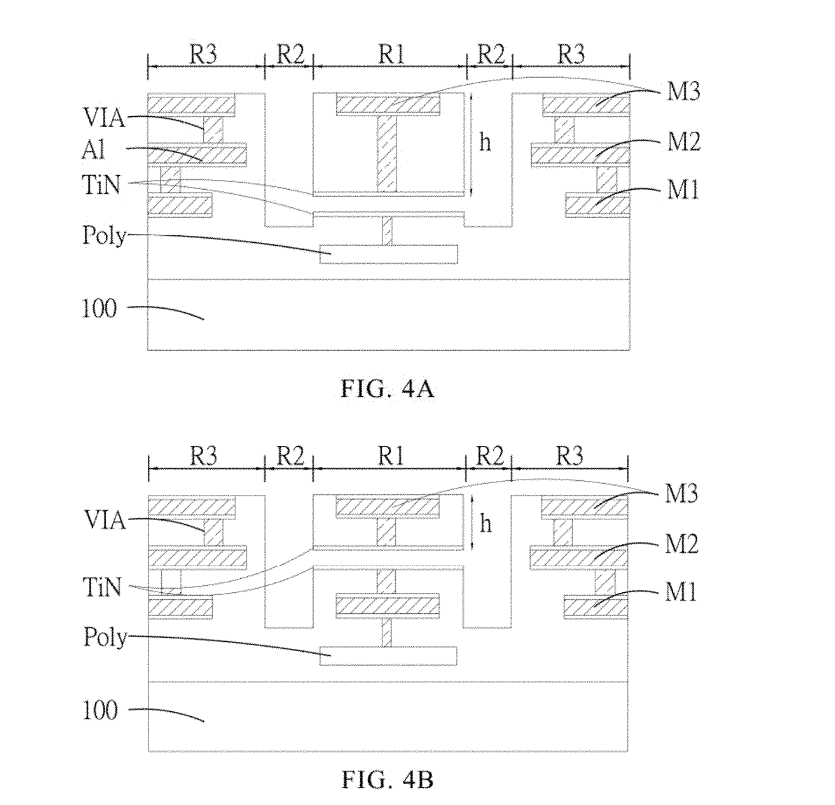

Refer to FIGS. 4A and 4B which are respectively the sectional views of the CMOS-MEMS resonant transducer in the FIG. 3A taken along line II-II. As shown in the figures, it is apparent from the other side of the free-free beam structure that the resonant body 102 on the silicon substrate 100 can be divided into a resonant body region R1, an etching region R2 and a wire bonding region R3 each having a plurality of TiN—Al—TiN composite layers which serve as electrodes M1, M2 and M3 respectively. The TiN—Al—TiN composite layer at the wire bonding region R3 is exposed to serve as probing pad. In this configuration, the height of the resonant body 102 may be 3.4 μm, and the resonant frequency of such structure is approximately 13 MHz. as mentioned before, the bottom of the resonant body 102 is covered with TiN layer TiN, and accordingly, a portion of the silicon dioxide layer SiO₂ under the resonant body 102 corresponding thereto is covered with TiN layer TiN, both of them have the same area such that the conduction of electrostatic charge is improved and the frequency drift is eliminated. Preferably, the present embodiment is applicable to the 0.35 μm CMOS-MEMS process platform, which is further applicable to the Back End Of Line (BEOL) CMOS fabrication process of other Al—Cu interconnect, such as the 0.25 μm, 0.18 μm, and etc. fabrication process. The detailed description of the fabrication process will be given hereinafter.

Besides the aforementioned architecture, the CMOS-MEMS resonant transducer can be configured in the way shown in FIG. 4B, the difference between the former embodiment and the present embodiment is that, the TiN—Al—TiN composite layer in the middle of the resonant body 102 can be etched to form the bottom of the resonant body 102 covered with the TiN layer similar to the previous embodiment. Besides, the portion, covered with the TiN layer, situated on the SiO₂ layer under the resonant body 102, excluding the support beam SUP, and opposite of the resonant body 102, can be formed with the configuration in FIG. 4B. This architecture can improve the electrostatic charge conductivity to eliminate the frequency drift as well. In that the resonant body 102 may be 1.76 μm in height h, the resonant frequency of such structure is about 13 MHz. Consequently, the resonant frequency of the CMOS-MEMS resonant transducer can be tailored according to the user's requirement by adjusting the height h of the resonant body 102.

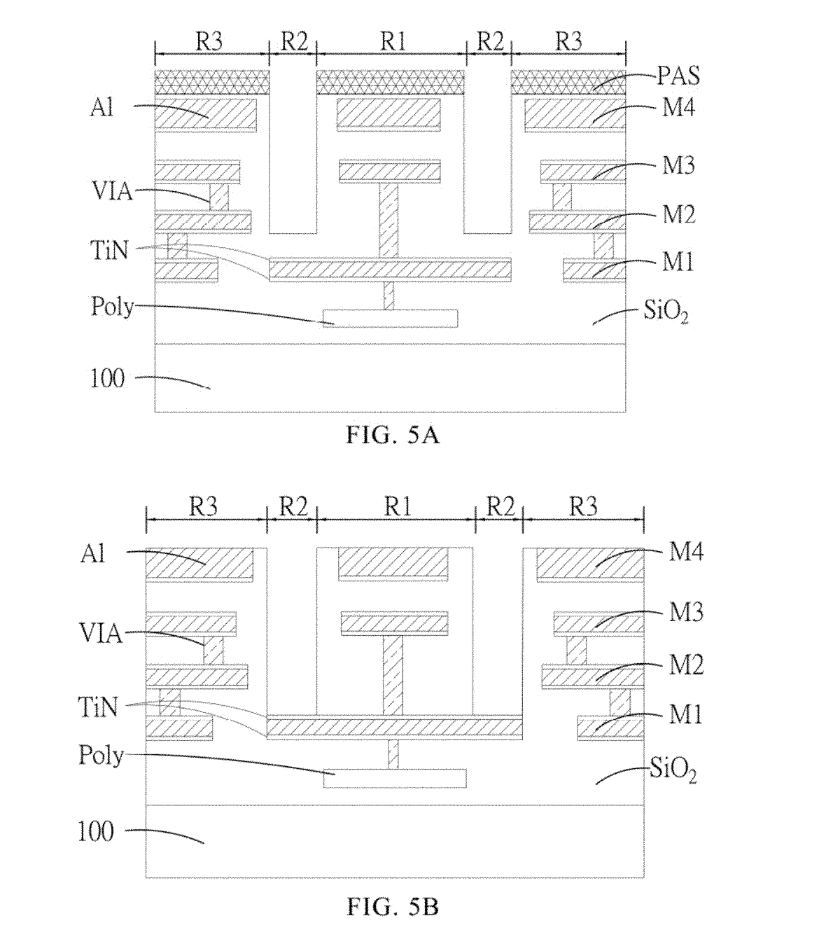

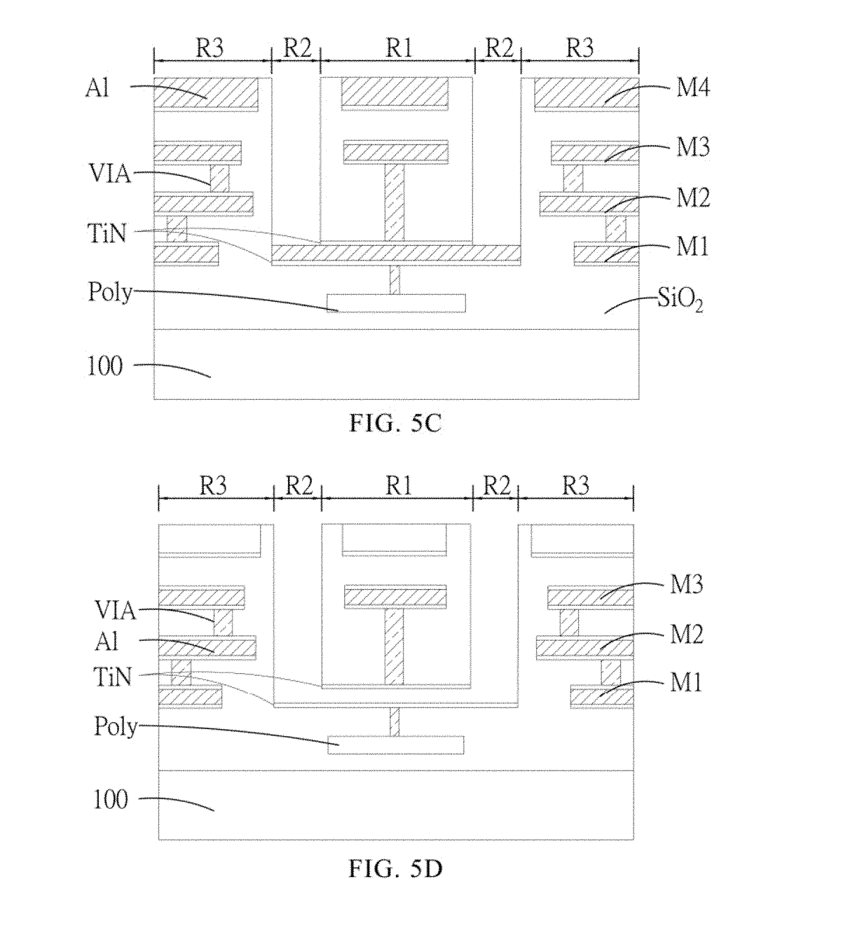

The method for fabricating the CMOS-MEMS resonant transducer of the present invention will be set forth hereinafter with reference to the accompanying drawings. The method is based on the CMOS-MEMS platform, which aims to fabricate the structure of the CMOS-MEMS resonant transducer shown in FIG. 4A. FIGS. 5A to 5D are respectively the sectional views illustrating every step of the method for fabricating the CMOS-MEMS resonant transducer according to an embodiment of the present invention. Wherein the pre-release CMOS-MEMS platform includes at least sequentially, the passivation layer PAS, a plurality of SiO₂ layers with a plurality of TiN—Al—TiN composite layers therein and a plurality of Al—TiN composite layers. The fabrication method includes the steps listed below:

Step S501: Etching the passivation layer PAS on the CMOS-MEMS platform which is at both sides of the resonant body region R1 for defining the resonant body region R1, etching region R2 at both sides adjacent to the resonant body region R1, as well as the wire bonding region R3 adjacent to the etching region R2;

Step S502: Etching a plurality of TiN—Al—TiN and Al—TiN composite layers in the etching region R2 to expose and the SiO₂ layer at the bottom of the etching region R2, as shown in FIG. 5A. Wherein, preferably metal wet etching process can be applied, and the etchant may utilize solution that contains H₂O₂ added with H₂SO₄, but not limited thereto;

Step S503: Etching the passivation layer PAS in the wire bonding region R3 as well as the exposed SiO₂ layer in the etching region R2 at both sides of the resonant body region R1 to expose the Al—TiN composite layer in the wire bonding region R3, and causing the TiN—Al—TiN composite layer at the bottom of the etching region R2 and the resonant body region R1 to expose the portion in the etching region R2, as shown in FIG. 5B. The dielectric reactive-ion etching system (Dielectric RIE-10NR) can be applied in the step, but not limited thereto;

Step S504: Etching TiN layer on the TiN—Al—TiN composite layer in the etching region R2 to expose the Al layer to prepare for the suspension of the resonant body later, as shown in FIG. 5C; wherein, the metal reactive-ion etching system (Metal RIE-200L) with reactant gas of Ar and Cl₂ can be applied, but not limited thereto;

Step S505: Etching the Al layer of the wire bonding region R3, the resonant body region R1 and the etching region R2, making the resonant body suspended as well as forming the TiN layers facing each other, which are at the bottom of the resonant body and the portion of etched CMOS-MEMS platform opposite the resonant body; as well as forming the support beam in the former embodiment, as shown in the FIG. 5D, the metal wet etching can be applied in the embodiment, and the etchant of Al can be applied, with process temperature of 35° C., but not limited thereto;

Step S506: Etching the TiN layer in the wire bonding region R3 and the etching region R2 to expose the SiO₂ layer in the wire binding region R3 and the etching region R2, and further etching the SiO₂ layer in the wire binding region R3 and the etching region R2, in order to expose the TiN—Al—TiN composite layer in the wire bonding region R3, which will serve as probing pad, as well as completing the structure of the CMOS-MEMS resonant transducer shown in FIG. 4A. In this step, metal reactive-ion etching system (Metal RIE-200L) and dielectric reactive-ion etching system (Dielectric RIE-10NR) can be applied sequentially, but the embodiment is not limited thereto.

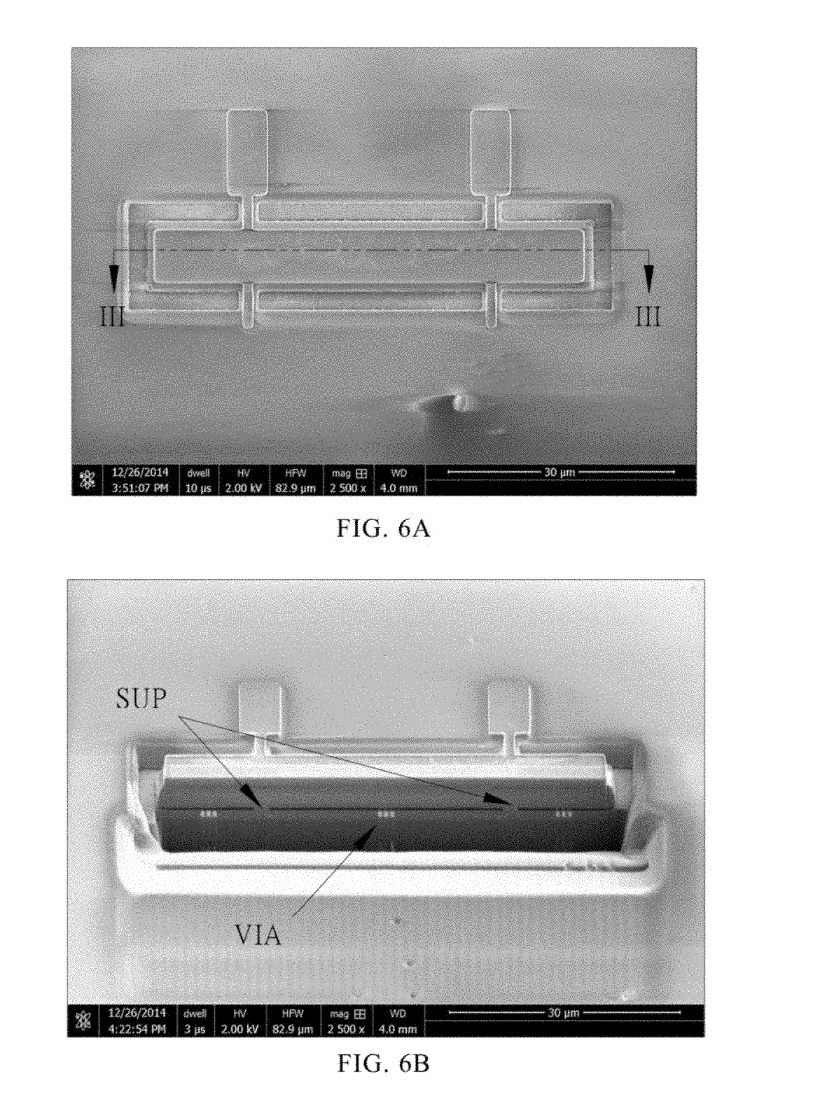

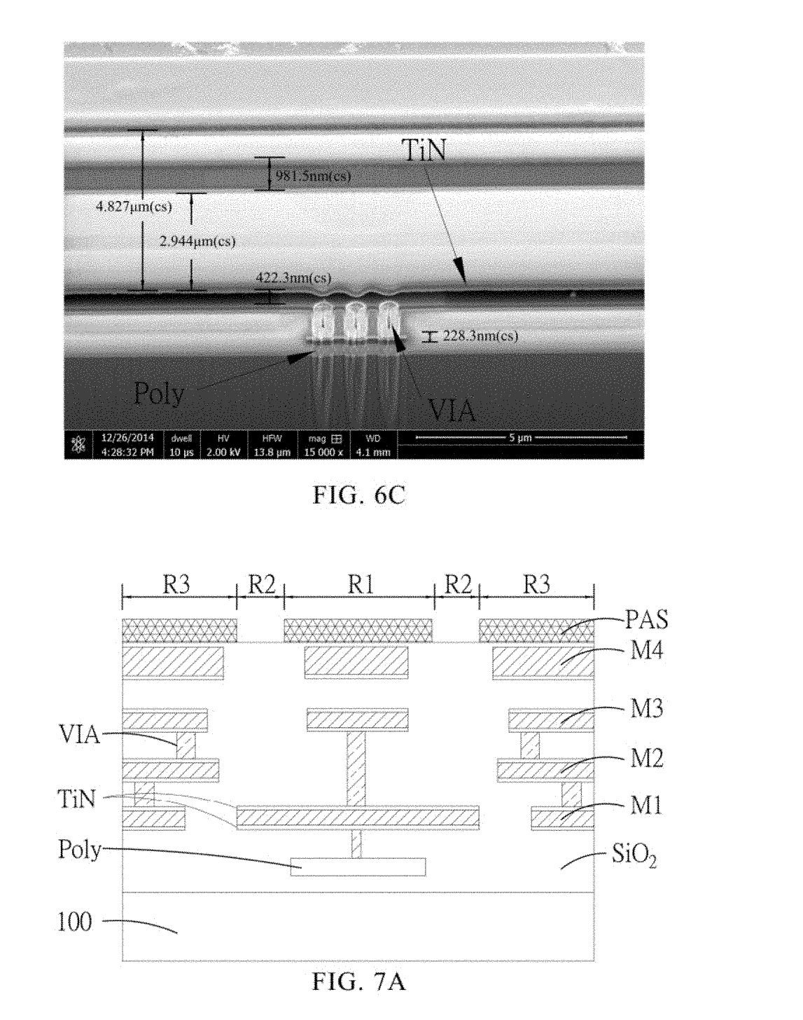

Reference should be made to FIGS. 6A to 6C, which are respectively the plan view SEM (scanning electron microscope), side view SEM taken along line III-III, and the partially magnified sectional view SEM of the resonant transducer fabricated using the method for fabricating the CMOS-MEMS resonant transducer of the present invention. From the aforementioned process, the free-free beam structure, the support beam, the TiN layer connected to the polysilicon electrode via the metal wiring, and air gap of approximately 400 nm may be formed. As shown in FIG. 6C, TiN layer is about 120 nm in thickness.

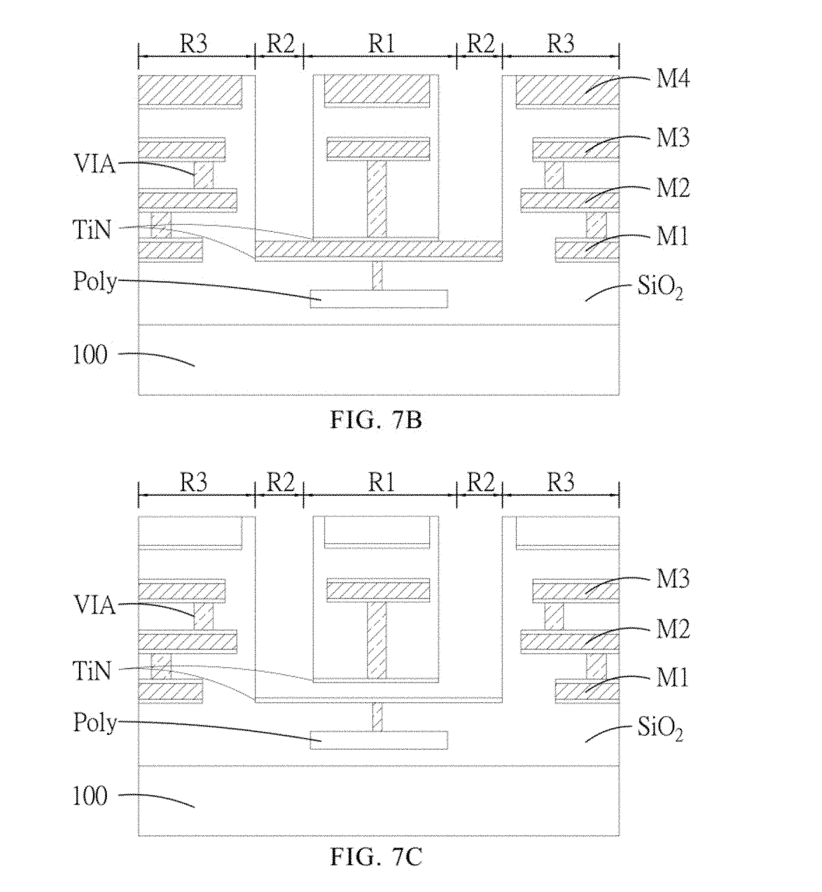

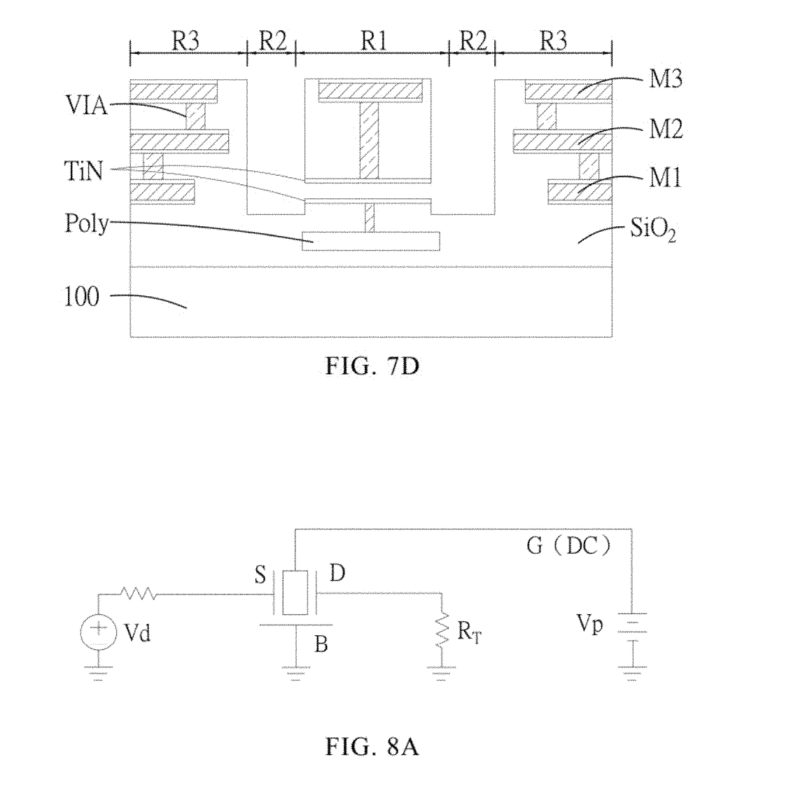

In addition, FIGS. 7A to 7D are respectively the sectional view illustrating every step of the method for fabricating the CMOS-MEMS resonant transducer according to another embodiment of the present invention. In the present method, the pre-release CMOS-MEMS platform includes at least sequentially, the passivation layer PAS, a plurality of SiO₂ layers with a plurality of TiN—Al—TiN composite layers therein and a plurality of Al—TiN composite layers. The fabrication method includes the steps listed below:

Step S701: Etching the passivation layer PAS on the CMOS-MEMS platform which is at both sides of the resonant body region R1, defining the resonant body region R1, etching region R2 at both sides adjacent to the resonant body region R1, as well as the wire bonding region R3 adjacent to the etching region R2, as shown in FIG. 7A;

Step S702: Etching the SiO₂ layer in the etching region R2 and the passivation layer PAS in the wire bonding region R3 to expose the Al—TiN composite layer in the wire bonding region R3, and causing the TiN—Al—TiN composite layer at the bottom of the etching region R2 and resonant body region R1 to expose the portion thereof belonging to the etching region R2. Dielectric reactive-ion etching system (Dielectric RIE-10NR) can be applied in this step, but not limited thereto;

Step S703: Etching TiN layer on the TiN—Al—TiN composite layer in the etching region R2 to expose the Al layer to prepare for the suspension of the resonant body later, as shown in FIG. 7B. The metal reactive-ion etching system (Metal RIE-200L) with reactant gas of Ar and Cl₂ can be applied in the present step, but not limited thereto;

Step S705: Etching the Al layer of the wire bonding region R3, resonant body region R1 and the etching region R2, while making the resonant body suspended as well as forming the TiN layers facing each other, which are at the bottom of the resonant body and the portion of etched CMOS-MEMS platform opposite the resonant body; as well as forming the support beam in the former embodiment, as shown in FIG. 7C. The metal wet etching processes can be applied in the present embodiment, and the etchant of Al can be applied, with process temperature of 35° C., but not limited thereto;

Step S705: Etching the TiN layer in the wire bonding region R3 and the etching region R2 to expose the SiO₂ layer in the wire binding region R3 and the etching region R2, and further etching the SiO₂ layer in the wire binding region R3 and the etching region R2, in order to expose the TiN—Al—TiN composite layer in the wire bonding region R3 as shown in FIG. 7D, which will serve as probing pad, as well as completing the structure of the CMOS-MEMS resonant transducer shown in FIG. 4A. In this step, the metal reactive-ion etching system (Metal RIE-200L) and the dielectric reactive-ion etching system (Dielectric RIE-10NR) can be applied sequentially, but the embodiment is not limited thereto. As shown in the figure, with the foregoing fabrication process, the free-free beam structure, the support beam, the TiN layer connected to the polysilicon electrode via the metal wiring, and air gap approximately smaller than 500 nm can be formed.

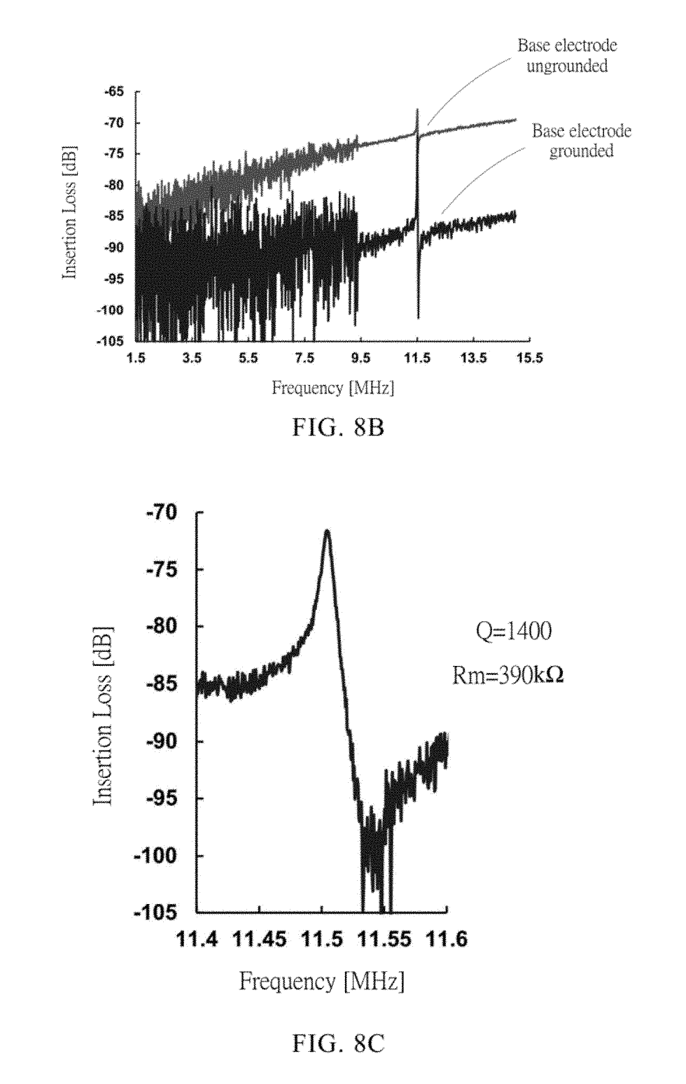

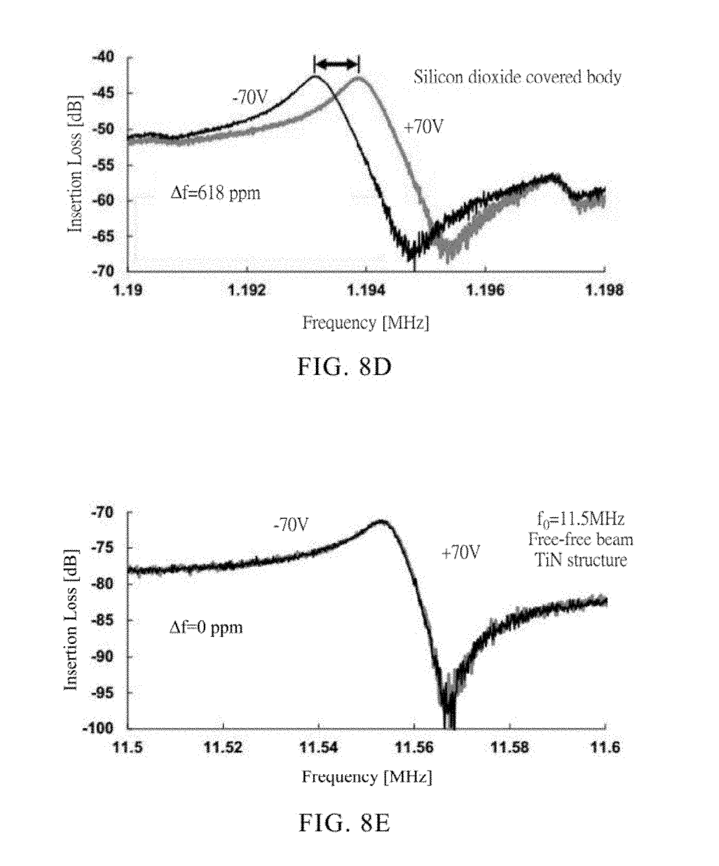

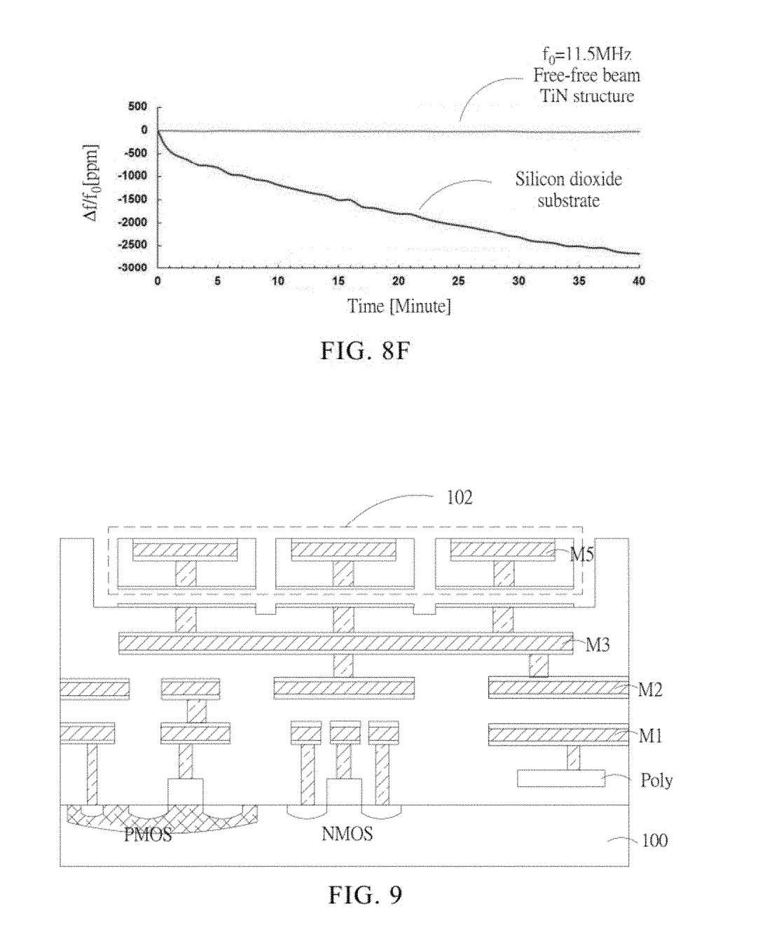

In order to suspend the resonant transducer, the entire component including a portion of transistor will be treated with the post-fabrication process of wet etching; in order to verify the properties of the etched transistor, the measurement of the transistor before and after the fabrication process must be made. Refer to the FIGS. 8A to 8E, which are respectively the experimental scheme and measurement results for the frequency characteristics of the CMOS-MEMS resonant transducer of the present invention. As shown in the figures, the experimental scheme can be in the form shown in 8A, the source and drain electrodes are respectively connected to a voltage source and a ground terminal, and the base electrode is grounded like the silicon substrate in the former embodiments. Various voltages Vp are applied to the gate electrode for measuring the frequency characteristics. As shown in the FIGS. 8B and 8C, when the base electrode is grounded, and the voltage Vp equals to 70V and is applied to the gate electrode, noise caused by the floating base effect of the base electrode can be reduced, and the quality factor Q can be 1400 and the motional impedance Rm can be 390 kg.

Besides, as shown in the FIGS. 8D and 8E, when the voltage applied to the gate electrode is Vp=±70V, contrary to the resonant body structure without utilizing the silicon dioxide covered with TiN layer, the frequency drift due to electrostatic effects can be evidently eliminated. However the present invention is not limited thereto, the method for fabricating the CMOS-MEMS resonant transducer of the present invention is applicable to common dielectric coated structures, and as shown in the FIG. 8F, by continuously tracking the characteristics of the structure of the present invention and a resonant transducer with oxide-metal substrate under applied voltage Vp for 40 minutes, it is evident that the CMOS-MEMS resonant transducer of the present invention can eliminate the frequency drift due to prolonged charge accumulation. In a nutshell, no evident frequency drift is observed from the characteristics curve of the CMOS-MEMS resonant transducer of the present invention, therefore, it is understood that the configuration of air gap lesser than 500 nm (400 nm in the present embodiment) and the TiN layer has certainly solved the frequency drift problem aforementioned.

Referring to FIG. 9, it is a sectional diagram illustrating the CMOS-MEMS resonant transducer according to yet another embodiment of the present invention. As shown in the figure, the CMOS-MEMS process platform of 180 nm is applicable to the CMOS-MEMS resonant transducer of present embodiment, which further includes a plurality of resonant bodies 102. Under the circumstances, the required applied voltage Vp can be further reduced, thereby improving the applicability of the present invention to various CMOS-MEMS process platforms. In addition, for the CMOS-MEMS resonant transducer and the method for fabricating thereof, additional resonant bodies can be fabricated using semiconductor fabrication process on the CMOS-MEMS platform. For example, one can stack the amorphous silicon or other types of dielectric material upwards, and deposit nitrides such as TiN, thallium nitride (TaN) or nitrogen silicon oxide (SiON) or tungsten compound such as titanium tungsten (TiW) in the wire bonding region using low temperature deposition process provided that the CMOS circuit at the bottom is not damaged, so as to form the sensing electrode and achieve better frequency stability.

All in all, the CMOS-MEMS resonant transducer and the method for fabricating thereof can fabricate the resonant transducer with high yield and precision in addition to having the free-free beam structure, the support beam constructed from dielectric material, the gap design with less than 500 nm, and the bottom of the resonant body structure formed from TiN layer coated silicon dioxide. Such invention can provide resonant transducer with low motional impedance as well as eliminate frequency drift due to the charge accumulation at the bottom of the resonant body. Besides, the CMOS-MEMS resonant transducer of the present invention has high adaptability to CMOS-MEMS process platform of various scales as well as matches the commercial platforms for the fabrication process of various manufacturers.

What is claimed is:

1. A method for fabricating CMOS-MEMS resonant transducer based on a CMOS-MEMS platform at least sequentially comprising a passivation layer, a plurality of dielectric layers with a plurality of titanium nitride (TiN)-metal-TiN layers therein, and a plurality of metal-TiN composite layers, the method comprising:
etching the passivation layer at both sides of a resonant body region in a middle of the CMOS-MEMS platform so as to define the resonant body region, an etching region adjacent to both sides of the resonant body region, and a wire bonding region adjacent to the etching region;
etching the plurality of the TiN-metal-TiN composite layers and the plurality of metal-TiN composite layers in the etching region to expose the dielectric layer in the etching region;
etching the passivation layer in the wire bonding region and the exposed dielectric layer in the etching region at both sides of the resonant body region to expose the metal-TiN composite layer in the wire bonding region, and causing TiN-metal-TiN composite layer at a bottom of the etching region and the resonant body region to expose a portion thereof belonging to the etching region;
etching a TiN layer on the TiN-metal-TiN composite layer in the etching region;
etching a metal layer of the wire bonding region, resonant body region and the etching region, making a resonant body coated with the dielectric layer suspended, and forming the TiN layers facing each other, the TiN layers being at a bottom of the resonant body and a portion of the etched CMOS-MEMS platform opposite the resonant body;
etching the TiN layer in the wire bonding region and the etching region to expose the dielectric layer in the wire bonding region and the etching region; and
etching the dielectric layer in the wire bonding region and the etching region, exposing the TiN-metal-TiN composite layer in the wire bonding region to serve as a probing pad for subsequent wire bonding process.

2. The method for fabricating CMOS-MEMS resonant transducer of claim 1, wherein in the step for defining the resonant body region, the etching region and the wire bonding region, the etching process is further applied to simultaneously etch the passivation layer on the resonant body region, etching region and the wire bonding region; and to etch the dielectric layer in the etching region, in order to expose the metal-TiN composite layer in the wire bonding region and to cause the TiN-metal-TiN composite layer at the bottom of the etching region and the resonant body region to expose a portion thereof belonging to the etching region.

3. The method for fabricating CMOS-MEMS resonant transducer of claim 1, wherein the plurality of TiN-metal-TiN composite layers and the plurality of metal-TiN composite layers in the dielectric layer further comprise a plurality of interconnected metal wirings therebetween.

4. The method for fabricating CMOS-MEMS resonant transducer of claim 1, wherein the resonant body is connected to the etched CMOS-MEMS platform through at least one dielectric layer, making the resonant body attach to the etched CMOS-MEMS platform in a suspended manner.

5. The method for fabricating CMOS-MEMS resonant transducer of claim 4, wherein areas of the TiN layer at the bottom of the resonant body and the portion of the CMOS-MEMS platform opposite the resonant body are equivalent.

6. The method for fabricating CMOS-MEMS resonant transducer of claim 1, wherein a gap between the bottom of the resonant body and the portion of the CMOS-MEMS platform corresponding to the resonant body is lesser than 500 nm.

7. The method for fabricating CMOS-MEMS resonant transducer of claim 1, wherein in the step for defining the resonant body region, the etching region and the wire bonding region, further comprises defining a plurality of resonant body regions, the etching region interposing the plurality of resonant body regions and surrounding the plurality of resonant body regions, and the wire bonding region surrounding the plurality of resonant body regions and the etching region, so as to form a plurality of resonant bodies.

8. The method for fabricating CMOS-MEMS resonant transducer of claim 1, wherein in the step for making the resonant body suspended further comprises using a semiconductor fabrication process to fabricate additional resonant body, and forming an electrode with a low temperature deposition process to deposit nitrides or tungsten compound at the wire bonding region.

9. A CMOS-MEMS resonant transducer comprising:
a silicon substrate with a resonant body region, an etching region surrounding the resonant body region, and a wire bonding region surrounding the etching region defined thereon;
a first dielectric layer, disposed on the silicon substrate, covering the silicon substrate, and comprising a polysilicon layer disposed in the resonant body region;
a second dielectric layer disposed in the wire bonding region;
a third dielectric layer disposed on the first dielectric layer in the resonant body region, the third dielectric layer connecting to the first dielectric layer via at least one resonant body support element, so as to form a resonant body coated with the first dielectric layer and suspended in the resonant body region;
a pair of TiN layers respectively covering a bottom of the resonant body and a portion of the third dielectric layer opposite the resonant body excluding the at least one resonant body support element; and
a plurality of TiN-metal-TiN composite layers interconnected via metal wirings and disposed in the second dielectric layer and the resonant body;
wherein, a top portion of the second dielectric layer and the resonant body expose a top portion of the plurality of TiN-metal-TiN composite layers; and the plurality of TiN-metal-TiN composite layers exposed in the wire bonding region subsequently serve as a probing pad.

10. The CMOS-MEMS resonant transducer of claim 9, wherein an area of the TiN layers at the bottom of the resonant body is equivalent to an area of the portion of the third dielectric layer opposite the resonant body.

11. The CMOS-MEMS resonant transducer of claim 9, wherein a gap between the bottom of the resonant body and the portion of the third dielectric layer opposite the resonant body is lesser than 500 nm.

12. The CMOS-MEMS resonant transducer of claim 9, wherein the silicon substrate further comprises a plurality of resonant body regions, with the etching region interposing the plurality of resonant body regions and surrounding the plurality of resonant body regions, and the wire bonding region surrounding the plurality of resonant body regions and the etching region, so as to form a plurality of resonant bodies.

13. The CMOS-MEMS resonant transducer of claim 9, further comprising an additional resonant body fabricated using semiconductor fabrication process, and an electrode formed with low temperature deposition process to deposit nitrides or tungsten compound at the wire bonding region.
